(19) United States
(12) Patent Application Publication
(10) Pub. No.: US 2023/0400506 A1
(43) Pub. Date: Dec. 14, 2023

(54) TEMPERATURE CONTROL SYSTEM AND METHOD FOR ELECTRONIC DEVICE-TESTING APPARATUS

(71) Applicant: CHROMA ATE INC., Taoyuan City (TW)

(72) Inventors: Chin-Yi OUYANG, Taoyuan City (TW); I-Ching TSAI, Taoyuan City (TW); Xin-Yi WU, Taoyuan City (TW); Yan-Lin WU, Taoyuan City (TW)

(21) Appl. No.: 18/316,691

(22) Filed: May 12, 2023

(30) Foreign Application Priority Data
Jun. 10, 2022 (TW) 111121595

(51) Int. Cl. G01R 31/28

(52) U.S. Cl. CPC G01R 31/2877; G01R 31/2863

(57) ABSTRACT

The present invention relates to a temperature control system and a temperature control method for an electronic device-testing apparatus. The temperature control system mainly includes a test socket, a temperature-controlling fluid supply device and a temperature-controlling fluid recovery device. A temperature-controlling fluid is supplied to a chip slot of the test socket by the temperature-controlling fluid supply device and drawn from the chip slot by the temperature-controlling fluid recovery device. In the present invention, the temperature-controlling fluid is forced to flow through the chip slot loaded with an electronic device so as to forcibly exchange heat with the electronic device and components in the chip slot, thereby achieving the constant temperature test. After the test is completed, the temperature-controlling fluid can be effectively recovered so that the contamination of the electronic device or the testing apparatus can be avoided.

### FIELD OF THE INVENTION

The present invention relates to a temperature control system and method for an electronic device-testing apparatus, in particular to a temperature control system and method for an electronic device under test and a testing apparatus.

### DESCRIPTION OF THE PRIOR ART

As the chip processing or computing function becomes more powerful, the chip has more contacts on its bottom surface, and the number and the distribution density of probes in the test socket of the testing apparatus have to be increased. Due to the increasingly complex function, the time necessary for execution of the test becomes longer, and the power required for the test is increased. Accordingly, great heat generated when the chip is tested is directly conducted to the solder balls of the chip and the probes.

Generally, the melting point of the solder balls is 180° C., but the solder balls begin to be softened gradually when the solder balls are heated to 120° C. On the other hand, when the power upon execution of the test reaches 900 W to 1,000 W, the solder balls would be heated to 120° C. However, according to the specifications of the existing chips, power necessary for testing the chips with complex functions often reaches a level between 800 W and 2,600 W. Therefore, during execution of the test, the solder balls are often melted and adhered to the probes, or the solder scraps remain in the test socket. After a period of time, it may lead to failure of the test, and it may lead to short circuits at worst, resulting in damage of the chip or failure of the testing apparatus.

In a conventional temperature control system of an existing chip-testing apparatus, the temperature of the chip is regulated by means of a pressing head. The pressing head is provided with a temperature controller and is brought into contact with the chip so that the temperature controller can heat or cool the chip. However, since the material of the chip itself has thermal resistance, great heat generated by the chip during execution of the test would cause a temperature gradient in the thickness direction. In the case of a low temperature test where the temperature controller of the pressing head is set to −40° C., if the chip is tested at a power of 1,000 W, the lower surface of the chip may reach −5° C. A considerable temperature difference is formed and may easily affect the accuracy of the test.

As such, a temperature control system capable of effectively and instantly cooling the chip, the solder balls, the test socket and the probes and of creating a constant temperature test environment for a semiconductor chip-testing apparatus is highly expected in the industry.

### SUMMARY OF THE INVENTION

The main object of the present invention is to provide a temperature control system and a temperature control method for an electronic device-testing apparatus capable of controlling the temperatures of an electronic device, solder balls, a test socket and probes. The present invention can not only prevent the solder balls from being molten by cooling the solder balls and the probes but also can create a constant temperature test environment.

To achieve the above object, a temperature control system for an electronic device-testing apparatus according to the present invention mainly comprises a test socket, a temperature-controlling fluid supply device and a temperature-controlling fluid recovery device. The test socket includes a chip slot, at least one fluid inlet portion and at least one fluid outlet portion. The fluid inlet portion and the fluid outlet portion are communicated with the chip slot; the temperature-controlling fluid supply device is communicated with the fluid inlet portion of the test socket; the temperature-controlling fluid recovery device is communicated with the fluid outlet portion of the test socket. When an electronic device is to be tested, the electronic device is accommodated in the chip slot of the test socket, the temperature-controlling fluid supply device supplies a temperature-controlling fluid to the chip slot through the fluid inlet portion, and the temperature-controlling fluid recovery device draws the temperature-controlling fluid from the chip slot of the test socket through the fluid outlet portion.

Accordingly, during execution of the test, the temperature control system for the electronic device-testing apparatus according to the present invention is capable of supplying the temperature-controlling fluid into the chip slot by means of the temperature-controlling fluid supply device for controlling the temperatures of the electronic device, solder balls, the test socket and probes. For example, these components are cooled for preventing the solder balls from being molten by high temperature during execution of the test. On the other hand, the temperature of the electronic device can be regulated by the temperature-controlling fluid for a high or low temperature test. More importantly, in the present invention, the temperature-controlling fluid recovery device is further used to draw and recover the temperature-controlling fluid so that the temperature-controlling fluid can be forced to flow or circulate. The temperatures of the temperature-controlling fluid and the electronic device in the chip slot can be effectively controlled so as to achieve a constant temperature control.

To achieve the above objective, a temperature control method for an electronic device-testing apparatus according to the present invention comprises the steps of: supplying a temperature-controlling fluid to a chip slot of a test socket by means of a temperature-controlling fluid supply device, an electronic device being accommodated in the chip slot, and a fluid-accommodating space being defined by a lower surface of the electronic device and the chip slot; making the temperature-controlling fluid flow through the fluid-accommodating space; and drawing the temperature-controlling fluid from the chip slot by means of a temperature-controlling fluid recovery device.

In other words, the present invention provides a novel temperature control method for an electronic device-testing apparatus, in which the temperature-controlling fluid supply device is used to supply the temperature-controlling fluid to the chip slot of the test socket, and the temperature-controlling fluid recovery device is used to draw the temperature-controlling fluid from the chip slot. The method of the present invention forces the temperature-controlling fluid to flow through the chip slot loaded with the electronic device so as to forcibly exchange heat with the electronic device and components in the chip slot, thereby achieving the purpose of testing the electronic device at a constant temperature. After the test is completed, the temperature-controlling fluid can be effectively recovered to prevent foreign matter from contaminating the electronic device or the testing apparatus.

### BRIEF DESCRIPTION OF DRAWINGS

FIG. 1 is a schematic configuration diagram of a preferred embodiment of a temperature control system according to the present invention.

FIG. 2 is a schematic architecture diagram of a preferred embodiment of the temperature control system according to the present invention.

FIG. 3A is a perspective view of a preferred embodiment of a test socket of the present invention.

FIG. 3B is an exploded view of a preferred embodiment of the test socket of the present invention.

FIG. 3C is a cross-sectional view of a preferred embodiment of the test socket of the present invention.

FIG. 4A is a graph showing the relationship between time and temperature difference between an inlet and an outlet for three different flow rates of a temperature-controlling fluid in the case that a test load is 400 W.

FIG. 4B is a graph showing the relationship between time and temperature difference between the inlet and the outlet for the three different flow rates of the temperature-controlling fluid in the case that a test load is 600 W.

FIG. 5A is a graph showing the relationship between time and heat load for the three different flow rates of the temperature-controlling fluid in the case that a test load is 400 W.

FIG. 5B is a graph showing the relationship between time and heat load for the three different flow rates of the temperature-controlling fluid in the case that a test load is 600 W.

FIG. 6 is a schematic configuration view of another preferred embodiment of the temperature control system according to the present invention.

### DETAILED DESCRIPTION OF THE INVENTION

Before a temperature control system and a method for an electronic device-testing apparatus according to the present invention is described in detail in embodiments, it should be noted that in the following description, similar components will be designated by the same reference numerals. Furthermore, the drawings of the present invention are for illustrative purposes only, they are not necessarily drawn to scale, and not all details are necessarily shown in the drawings.

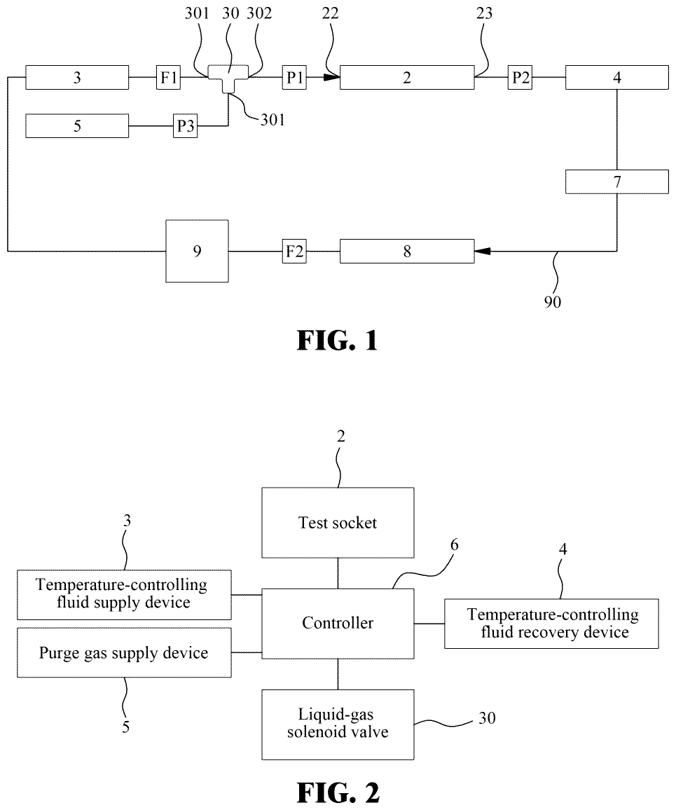

Reference is made to FIG. 1 and FIG. 2. FIG. 1 is a schematic configuration diagram of a preferred embodiment of the system according to the present invention, and FIG. 2 is a schematic architecture diagram of a preferred embodiment of the system according to the present invention. As shown in the figures, the temperature control system mainly includes a test socket 2, a temperature-controlling fluid supply device 3, a temperature-controlling fluid recovery device 4, a purge gas supply device 5, a controller 6, a filter module 7, a heat exchanger 8, a temperature-controlling fluid tank 9, a liquid-gas solenoid valve 30 and a fluid circulation channel 90, wherein the test socket 2, the temperature-controlling fluid supply device 3, the temperature-controlling fluid recovery device 4, the purge gas supply device 5 and the liquid-gas solenoid valve are electrically connected to the controller 6.

The fluid circulation channel 90 is communicated between the temperature-controlling fluid supply device 3 and the temperature-controlling fluid recovery device 4. The filter module 7, the heat exchanger 8 and the temperature-controlling fluid tank 9 are communicated with the fluid circulation channel 90. In other words, as shown in FIG. 1, the entire apparatus forms a temperature-controlling fluid circulation system. A temperature-controlling fluid is supplied to the test socket 2 by the temperature-controlling fluid supply device 3 and is recovered from the test socket 2 by the temperature-controlling fluid recovery device 4, and then temperature-controlling fluid flows through the filter module 7 in the fluid circulation channel 90 for filtering molten scraps of solder balls or other foreign matters, and then flows into the heat exchanger 8 for being further cooled or heated. Finally, the temperature-controlling fluid flows into the temperature-controlling fluid tank 9 so that the temperature-controlling fluid supply device 3 can draw the temperature-controlling fluid. The temperature-controlling fluid in this embodiment is a non-conductive heat-conducting fluid such as 3M™ Novec™ engineered fluid.

The liquid-gas solenoid valve 30 includes two inlet ends 301 and an outlet end 302. The temperature-controlling fluid supply device 3 and the purge gas supply device are communicated with the two inlet ends 301 respectively, and the outlet end 302 is communicated with the test socket 2. The liquid-gas solenoid valve 30 is adapted to be switched under the control of the controller 6 for communicating the test socket 2 with the temperature-controlling fluid supply device 3 or the purge gas supply device 5.

In this embodiment, the entire circulation system is further provided with a first flowmeter F1, a second flowmeter F2, a first fluid pressure gauge P1, a second fluid pressure gauge P2 and a third fluid pressure gauge P3. The first flowmeter F1 is arranged between the temperature-controlling fluid supply device 3 and the liquid-gas solenoid valve 30 for measuring the flow rate of the temperature-controlling fluid supplied by the temperature-controlling fluid supply device 3. The second flowmeter F2 is arranged between the heat exchanger 8 and the temperature-controlling fluid tank 9 for measuring the flow rate of the recovered temperature-controlling fluid. The fact whether the temperature-controlling fluid leaks or the fluid circulation channel 90 is blocked can be determined by comparing the measurement results of the first flowmeter F1 and the second flowmeter F2. The first fluid pressure gauge P1 and the second fluid pressure gauge P2 are disposed on two sides of the test socket 2 for monitoring the pressures of the fluid flowing into the test socket land the fluid flowing from the test socket 2 respectively. The third fluid pressure gauge P3 is used for monitoring the pressure of a purge gas supplied by the purge gas supply device 5.

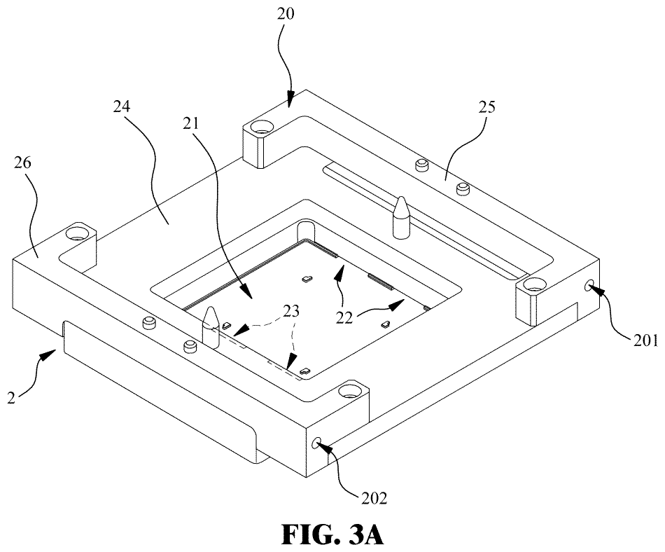

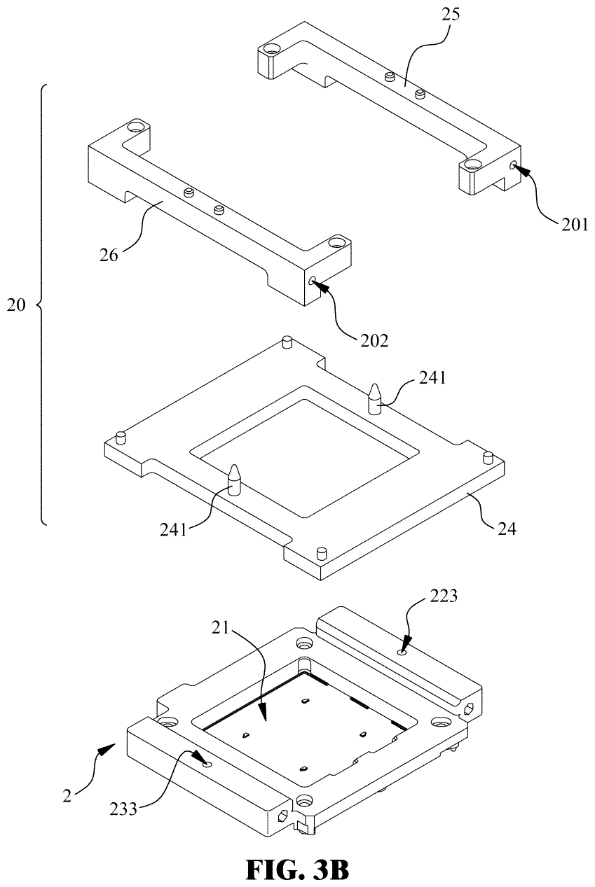

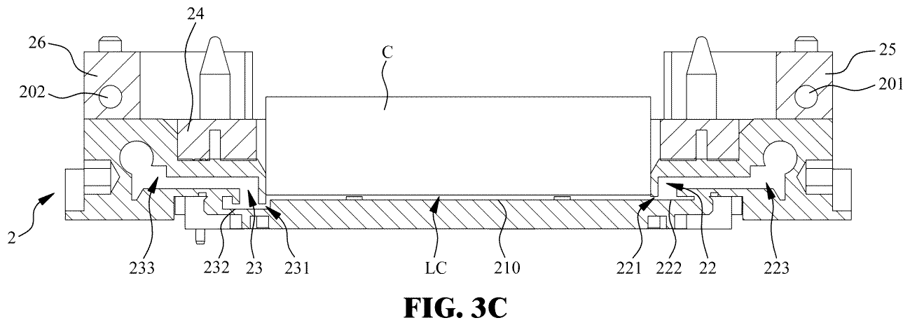

Reference is made to FIGS. 3A, 3B and 3C. FIG. 3A is a perspective view of a preferred embodiment of the test socket of the present invention, FIG. 3B is an exploded view of a preferred embodiment of the test socket of the present invention, and FIG. 3C is a cross-sectional view of a preferred embodiment of the test socket of the present invention.

The test socket 2 of this embodiment includes a chip slot 21, a fluid inlet portion 22 and a fluid outlet portion 23. The fluid inlet portion 22 includes two fluid inlet recesses 221 and a first channel 223. The fluid outlet portion 23 includes two fluid outlet recesses 231 and a second channel 233. The two fluid inlet recesses 221 and the two fluid outlet recesses 231 are disposed on two opposite sides of the chip slot 21 respectively and communicated with the chip slot 21. As shown in FIG. 3C, the bottom surface 222 of the fluid inlet recess 221 is flush with the bottom surface 210 of the chip slot 21, and the bottom surface 232 of the fluid outlet recess 231 is lower than the bottom surface 210 of the chip slot 21 in the thickness direction of the test socket 2 so that the fluid outlet recess 231 is arranged slightly lower than the chip slot 21 for facilitating the evacuation of temperature-controlling fluid in the chip slot 21.

A docking plate 20, which is composed of a positioning piece 24, a fluid inlet piece 25 and a fluid outlet piece 26, is disposed on the test socket 2. The positioning piece 24 is a square metal frame having an opening aligned with the chip slot 21. Two opposite sides of the positioning piece 24 each are provided with a positioning pin 241 for alignment of a pressing head (not shown in the figures). Accordingly, when a device under test is changed, only the test socket 2 needs to be replaced, and the docking plate 20 can be adapted to all test sockets. Therefore, it is beneficial for modification and maintenance of the apparatus.

As shown in the figure, the fluid inlet piece 25 and the fluid outlet piece 26 are disposed on the two opposite sides of the test socket 2 respectively. The fluid inlet piece 25 includes a fluid inlet channel 201, and the fluid outlet piece 26 includes a fluid outlet channel 202. The fluid inlet channel 201 is communicated with the fluid inlet recesses 221 through the first channel 223 of the fluid inlet portion 22, and the fluid outlet channel 202 is communicated with the fluid outlet recesses 231 through the second channel 233 of the fluid outlet portion 23. Accordingly, the temperature-controlling fluid supply device 3 and the purge gas supply device 5 can be communicated with the chip slot 21 through the fluid inlet channel 201, the first channel 223 and the fluid inlet recesses 221. Similarly, the temperature-controlling fluid recovery device 4 can be communicated with the chip slot 21 through the fluid outlet channel 202, the second channel 233 and the fluid outlet recesses 231.

The operation of this embodiment will be described below. Reference is made to FIG. 1 to FIG. 3C. First, an electronic device C is placed in the chip slot 21, and the lower surface of the electronic device C and the chip slot 21 define a fluid-accommodating space LC, as shown in FIG. 3C. Next, the controller 6 controls the liquid-gas solenoid valve 30 to establish communication between the temperature-controlling fluid supply device 3 and the outlet end 302 and controls the temperature-controlling fluid supply device 3 to supply the temperature-controlling fluid to the fluid-accommodating space LC. At the same time, the controller 6 also controls the temperature-controlling fluid recovery device 4 to draw the temperature-controlling fluid from the fluid-accommodating space LC. When the test of the electronic device C is completed, the controller 6 controls the temperature-controlling fluid supply device 3 to stop supplying the temperature-controlling fluid to the fluid-accommodating space LC and then controls the liquid-gas solenoid valve 30 to establish communication between the purge gas supply device 5 and the outlet end 302. At this time, the temperature-controlling fluid recovery device 4 continues drawing the temperature-controlling fluid from the fluid-accommodating space LC.

During the test process of the electronic device, on the one hand, the temperature-controlling fluid supply device 3 supplies the temperature-controlling fluid to the fluid-accommodating space LC, and on the other hand, the temperature-controlling fluid recovery device 4 draws the temperature-controlling fluid from the fluid-accommodating space LC, thereby forming a forced circulation of the temperature-controlling fluid. The temperature-controlling fluid exchanges heat with the lower surface of the electronic device C, solder balls, the test socket and probes in the fluid-accommodating space LC. Since the temperature-controlling fluid in the fluid-accommodating space LC is always forcibly circulated, even if no sealing means is provided between the four peripheral side walls of the electronic device C and the four peripheral inner side walls of the chip slot 21, the temperature-controlling fluid would not leak from the gaps of the electronic device C and the chip slot 21.

When the test is completed, the purge gas supply device 5 is used to supply the purge gas to the fluid-accommodating space LC. The purge gas supply device 5 in this embodiment can be a gas source supplied by a factory area or an independent air compressor. After the high-pressure purge gas is supplied into a fluid pipeline and the chip slot 21, the residual temperature-controlling fluid can be forced into a recovery pipeline, and the temperature-controlling fluid recovery device 4 continues drawing and forcibly recovering the temperature-controlling fluid.

In this embodiment, the temperature-controlling fluid recovery device 4 is normally turned on so that the forced circulation of the temperature-controlling fluid can be ensured when the temperature-controlling fluid supply device 3 supplies the temperature-controlling fluid to the fluid-accommodating space LC. After the test is completed, the temperature-controlling fluid recovery device 4 is still in operation while the purge gas supply device 5 supplies the purge gas to the fluid-accommodating space LC so that all the temperature-controlling fluid in the fluid-accommodating space LC can be completely recovered. Since the temperature-controlling fluid recovery device 4 of this embodiment is a diaphragm pump with the characteristic of good self-sucking ability, it can naturally and continuously evacuate the temperature-controlled fluid, and no residual fluid remains in the electronic device C and the chip slot 21.

On the other hand, the time interval between the completion of the test of the electronic device C and the replacement of the tested electronic device C with a new electronic component C under test may be smaller than 1 second. For this reason, the present invention provides another variant embodiment, in which only after the test of a batch of electronic devices C is completed, the purge gas supply device 5 would be activated so that the temperature-controlling fluid can be forcibly removed from the fluid-accommodating space LC by the purge gas and recovered by the temperature-controlling fluid recovery device 4. Therefore, during the test process of the batch of electronic devices, the temperature-controlling fluid supply device 3 and the temperature-controlling fluid recovery device 4 are normally turned on.

In this variant embodiment, since the temperature-controlling fluid recovery device 4 continuously draws the temperature-controlling fluid, the overflow of the temperature-controlling fluid from the chip slot 21 can be effectively avoided during replacement of the tested electronic device C with a new electronic device C under test. In order to completely prevent the temperature-controlling fluid from overflowing from the chip slot 21, before the tested electronic device C is picked up, the temperature-controlling fluid supply device 3 stop supplying the temperature-controlling fluid. After the next electronic device C under test is placed in the chip slot 21, the temperature-controlling fluid supply device 3 restarts supplying the temperature-controlling fluid. In this embodiment, the temperature-controlling fluid recovery device 4 continuously draws the temperature-controlling fluid.

The relevant data of the actual operation of this embodiment will be described below. In the case of by-passing the test socket 2, the temperature of the temperature-controlling fluid at the inlet of the chip slot 21 is 22.9° C., and the temperature of the temperature-controlling fluid at the outlet of the chip slot 21 is 23.1° C. so the temperature difference is 0.2° C. The entire temperature control system dissipates heat at 2 W. The fluid pressure at the inlet of the chip slot 21 is 9 kPa, and the fluid pressure at the outlet of the chip slot 21 is −32 kPa. In the case that the test socket 2 is loaded, when the temperature-controlling fluid is circulated at a flow rate of 0.17 LPM, the temperature of the temperature-controlling fluid at the inlet of the chip slot 21 is 23.1° C., and the temperature of the temperature-controlling fluid at the outlet of the chip slot 21 is 26.6° C. so the temperature difference is 3.5° C. Therefore, in the case that the test socket 2 is loaded without test load, the entire temperature control system dissipates heat at 7.8 W. The fluid pressure at the inlet of the chip slot 21 is 3 kPa, and the fluid pressure at the outlet is −10 kPa.

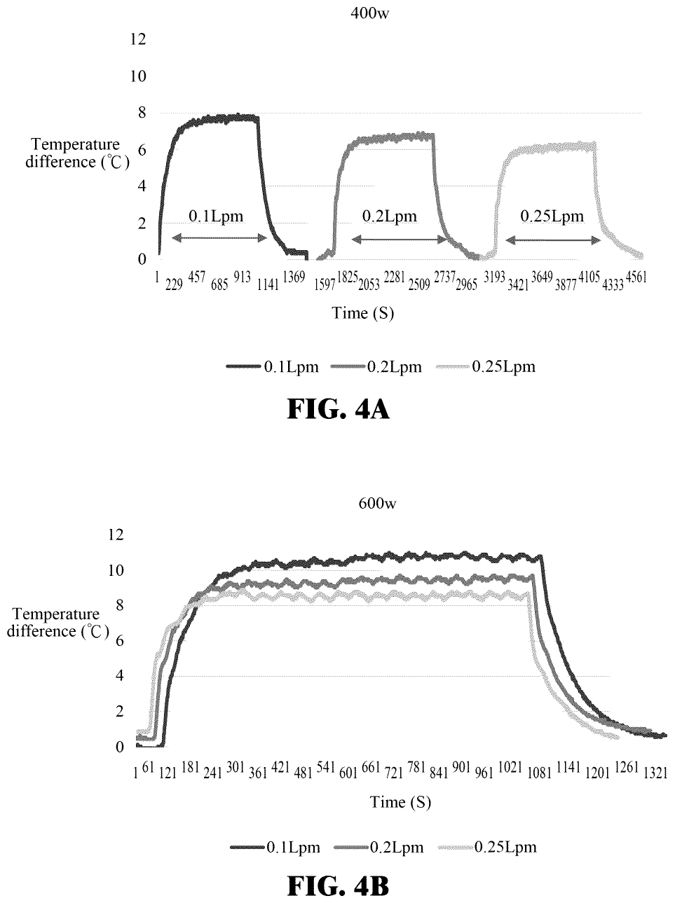

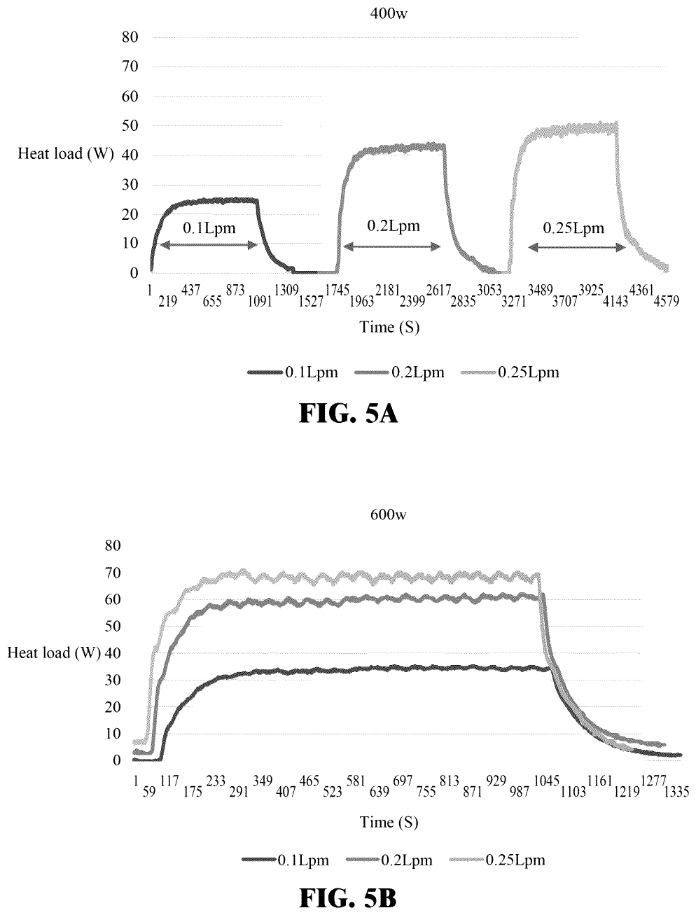

Reference is made to FIG. 4A, FIG. 4B, FIG. 5A and FIG. 5B. FIG. 4A and FIG. 4B each show the relationship of time and temperature difference between the inlet and outlet of the chip slot for three different flow rates of 0.1 LPM, 0.2 LPM and 0.25 LPM, using two different test loads of 400 W and 600 W respectively. Similarly, FIG. 5A and FIG. 5B each show the relationship of time and heat load for three different flow rates of 0.2 LPM and 0.25 LPM, using two different test loads of 400 W and 600 W respectively. It can be known from these figures that a smaller flow rate results in a larger temperature difference with less heat being dissipated by the system. In the case of the test load of 400 W, the flow rate of the temperature-controlling fluid is 0.1 LPM, the temperature difference between the inlet and the outlet is about 8° C., and heat is dissipated at about 25 W. If the flow rate of the temperature-controlling fluid is increased to 0.25 PM, the temperature difference between the inlet and the outlet drops to about 6° C., and heat is dissipated at about 50 W. In fact, a larger flow rate results in a smaller temperature difference between the inlet and the outlet with greater heat being dissipated by the system and hence is beneficial to maintenance of a constant temperature test environment.

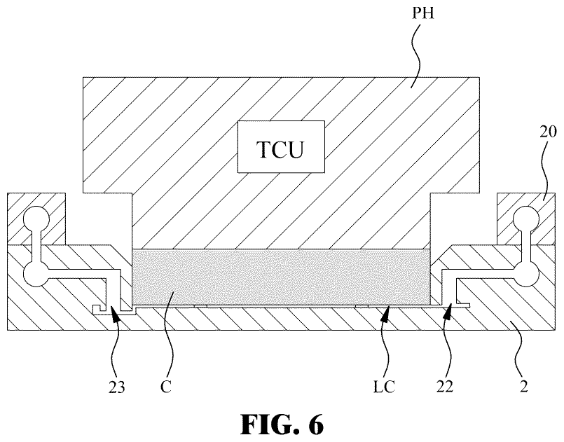

Reference is made to FIG. 6, which is a schematic view of another preferred embodiment of the temperature control system according to the present invention. This embodiment is further equipped with a pressing head PH, which is disposed above the test socket 2. The pressing head PH includes a thermal control unit (TCU), which can be a chilling device, an electric heating device, a heat exchanger having a temperature-controlling fluid circulation pipeline or other equivalent heating or cooling devices. When the electronic device C is to be tested, the pressing head PH approaches the test socket 2 and is pressed against the electronic device C, and the thermal control unit TCU regulates the temperature of the electronic device C to a specific temperature, for example, −40° C. On the other hand, the temperature of the temperature-controlling fluid circulating in the pipeline inside the test socket 2 and the fluid-accommodating space LC is set to the specific temperature, i.e. −40° C. Accordingly, this embodiment can create a completely constant temperature test environment so that the electronic device C can be tested at a constant test temperature, and accurate test results can be obtained.

The preferred embodiments of the present invention are illustrative only, and the claimed inventions are not limited to the details disclosed in the drawings and the specification. Accordingly, it is intended that it have the full scope permitted by the language of the following claims.

1. A temperature control system for an electronic device-testing apparatus, comprising:
a test socket, including a chip slot, at least one fluid inlet portion and at least one fluid outlet portion, the at least one fluid inlet portion and the at least one fluid outlet portion being communicated with the chip slot;
a temperature-controlling fluid supply device, communicated with the at least one fluid inlet portion of the test socket; and
temperature-controlling fluid recovery device, communicated with the at least one fluid outlet portion of the test socket,
wherein when an electronic device is tested, the electronic device is accommodated in the chip slot of the test socket, a temperature-controlling fluid is supplied to the chip slot through the at least one fluid inlet portion by the temperature-controlling fluid supply device and drawn from the chip slot of the test socket through the at least one fluid outlet portion by the temperature-controlling fluid recovery device.

2. The temperature control system of claim 1, further comprising a controller, which is electrically connected to the test socket, the temperature-controlling fluid supply device and the temperature-controlling fluid recovery device, wherein when the electronic device is tested, the controller controls the temperature-controlling fluid supply device to supply the temperature-controlling fluid to the chip slot and controls the temperature-controlling fluid recovery device to draw the temperature-controlling fluid from the chip slot of the test socket; when a test of the electronic device is completed, the controller controls the temperature-controlling fluid supply device to stop supplying the temperature-controlling fluid to the chip slot and controls the temperature-controlling fluid recovery device to continue drawing the temperature-controlling fluid from the chip slot of the test socket.

3. The temperature control system of claim 2, further comprising a purge gas supply device, which is electrically connected to the controller and communicated with the at least one fluid inlet portion of the test socket, wherein when the test of the electronic device is completed, the controller controls the temperature-controlling fluid supply device to stop supplying the temperature-controlling fluid to the chip slot and controls the purge gas supply device to supply a purge gas to the chip slot and controls the temperature-controlling fluid recovery device to continue drawing the temperature-controlling fluid from the chip slot of the test socket.

4. The temperature control system of claim 3, further comprising a filter module, a heat exchanger, a temperature-controlling fluid tank and a fluid circulation channel, wherein the fluid circulation channel is communicated between the temperature-controlling fluid supply device and the temperature-controlling fluid recovery device, and the filter module, the heat exchanger and the temperature-controlling fluid tank are communicated with the fluid circulation channel.

5. The temperature control system of claim 3, further comprising a liquid-gas solenoid valve, the liquid-gas solenoid valve including two inlet ends and an outlet end and being electrically connected to the controller, the temperature-controlling fluid supply device and the purge gas supply device being communicated with the two inlet ends respectively, the outlet end being communicated with the at least one fluid inlet portion of the test socket, wherein when the electronic device is tested, the controller controls the liquid-gas solenoid valve so that the temperature-controlling fluid supply device is communicated with the outlet end; when the test of the electronic device is completed, the controller controls the liquid-gas solenoid valve so that the purge gas supply device is communicated with the outlet end.

6. The temperature control system of claim 1, further comprising a docking plate, which is disposed on an upper surface of the test socket and includes a fluid inlet channel and a fluid outlet channel, wherein the temperature-controlling fluid supply device and the at least one fluid inlet portion are communicated with two ends of the fluid inlet channel respectively, the temperature-controlling fluid recovery device and the at least one fluid outlet portion are communicated with two ends of the fluid outlet channel respectively.

7. The temperature control system of claim 1, wherein the at least one fluid inlet portion includes at least one fluid inlet recess, and the at least one fluid outlet portion includes at least one fluid outlet recess; a bottom surface of the at least one fluid inlet recess is flush with a bottom surface of the chip slot; a bottom surface of the at least one fluid outlet recess is lower than the bottom surface of the chip slot in a thickness direction of the test socket.

8. The temperature control system of claim 1, further comprising a pressing head, which is arranged above the test socket, the pressing head including a thermal control unit, wherein when the electronic device is tested, the pressing head approaches the test socket and is pressed against the electronic device, the thermal control unit regulates a temperature of the electronic device to a specific temperature, which is equal to a temperature of the temperature-controlling fluid; when the test of the electronic device is completed, the pressing head moves away from the test socket.

9. A temperature control method for an electronic device-testing apparatus, comprising the steps of:
(A) supplying a temperature-controlling fluid to a chip slot of a test socket by a temperature-controlling fluid supply device, an electronic device being accommodated in the chip slot, and a fluid-accommodating space being defined by a lower surface of the electronic device and the chip slot;
(B) making the temperature-controlling fluid flow through the fluid-accommodating space; and
(C) drawing the temperature-controlling fluid from the chip slot by a temperature-controlling fluid recovery device.

10. The temperature control method of claim 9, after the step (C), the method further comprising a step (D), in which the temperature-controlling fluid supply device stops supplying the temperature-controlling fluid to the chip slot, a purge gas supply device supplies a purge gas to the chip slot, and the temperature-controlling fluid recovery device continues drawing the temperature-controlling fluid from the chip slot.
